(19) United States
(12) Patent Application Publication
(10) Pub. No.: US 2006/0198435 A1
(43) Pub. Date: Sep. 7, 2006

(54) Digital filter

(75) Inventors: Fuzuki Ishibashi, Yokohama-shi (JP); Mototsugu Shiraiwa, Yokohama-shi (JP)

Correspondence Address: PEARNE & GORDON LLP, 1801 EAST 9TH STREET, SUITE 1200, CLEVELAND, OH, 44114-3108, US

(73) Assignee: Matsushita Electric Industrial Co., Ltd., Osaka (JP)

(21) Appl. No.: 11/315,605

(22) Filed: Dec. 22, 2005

(30) Foreign Application Priority Data
Dec. 24, 2004 (JP) P.2004-374225

(51) Int. Cl. H03K 5/159

(52) U.S. Cl. 375/232

(57) ABSTRACT

To provide a digital filter that is small in its circuit scale and can suppress a consumed electric power to a low level. A multiplier 1, a first adder 2 and a second adder 3 perform a filtering calculation to data inputted to a digital filter 10. A first output data storing part 5 stores the output data of the second adder 3. A second output data storing part 6 stores the output data of the multiplier 1 and the first adder 2. A coefficient storing part 7 outputs the multiplication coefficient of the multiplier 1. An input selecting part 8 selects one of the input data and the output data of the digital filter 10 and outputs the data to the multiplier 1. A state control part 4 sets a plurality of different calculation states as one cycle and outputs a control signal for controlling the switching of the calculation states. A result obtained by performing a calculation of one cycle is outputted as the output data of the digital filter 10.

### BACKGROUND OF THE INVENTION

The present invention relates to a digital filter that is used for a signal processing part for communication data of a radio communication apparatus and performs a filtering process on input data to output the output data.

The digital filter means a digital signal processing system having a function for removing an unnecessary noise component from an observed signal to derive a desired signal component.

Assuming that an input signal is X and an output signal is Y, the signal process of the digital filter is expressed by a below-described mathematical formula 1 and a calculation represented by the mathematical formula 1 is carried out to realize a filtering function in a digital circuit.
[Mathematical Formula 1]

$$Y = \frac{{b}_{0} + {b}_{1} \cdot {z}^{- 1} + {b}_{2} \cdot {z}^{- 2} + {b}_{3} \cdot {z}^{- 3} + {b}_{4} \cdot {z}^{- 4} + {b}_{5} \cdot {z}^{- 5}}{{a}_{0} + {a}_{1} \cdot {z}^{- 1} + {a}_{2} \cdot {z}^{- 2} + {a}_{3} \cdot {z}^{- 3} + {a}_{4} \cdot {z}^{- 4} + {a}_{5} \cdot {z}^{- 5}} \cdot X \qquad [ Mathematical Formula 1 ]$$

a0 to a5, b0 to b5: filter coefficient
z: delay element

Ordinarily, in the digital filter, the above-described formula is calculated by a microprocessor exclusively used for a signal process that is called a digital signal processor (refer it to as a DSP, hereinafter) and software to perform the signal process.

When the DSP is not used, delay elements, a multiplication circuit and an addition circuit are formed with hardware to realize the calculation of the mathematical formula 1 (for instance, see JP-A-2004-242051).

However, under an actual state, when the usual digital filter uses the DSP, the DSP is expensive and a mounting area on a board is required.

Further, when the digital filter is formed only by the circuits without using the DSP, the multiplication and addition circuits of many bits are required for the number of stages of the filter, so that a circuit scale is enormously enlarged. As disclosed in JP-A-2004-242051, an example is provided in which a little improvement is performed that a necessary bit width is considered to change a sequence of calculations or the symmetry property of the filter coefficients is considered to reduce an amount of multiplication. However, since the number of the multiplication and addition circuits basically remains unchanged from that in the usual digital filter, the quantity of the circuits cannot be greatly reduced. Further, under the circumstances, since the circuit scale is large, a consumed electric power is undesirably increased.

### SUMMARY OF THE INVENTION

The present invention is proposed by considering the above-described circumstances and it is an object of the present invention to provide a digital filter having a small size in circuit scale and capable of suppressing a consumed electric power to a low level.

A digital filter according to the present invention performs a filtering process on input data to output the output data. The digital filter for performing a filtering process on inputted data to output the output data, includes a multiplier that multiplies the inputted data by a prescribed multiplication coefficient, a first adder that adds the output data of the multiplier to first adding data, a second adder that adds the output data of the first adder to second adding data, a state control part that controls to switch of a plurality of different calculation states, the calculation states being set as one cycle, a first storing part that stores the output data of the second adder, and outputs the output data of the second adder to the first adder as the first adding data in accordance with a state designated by the state control part, a second storing part that stores the output data of the first adder, and outputs the output data of the first adder to the second adder as the second adding data in accordance with a state designated by the state control part, a coefficient storing part that stores a plurality of filter coefficients and outputs the filter coefficient to the multiplier as the multiplication coefficient in accordance with the state designated by the state control part, an output storing part that stores the output data of the second adder for each cycle, and an input switching part that switches the data inputted to the multiplier to either the input data to the digital filter or the data stored in the output storing part in accordance with the state designated by the state control part.

According to this structure, since the plurality of calculation states are switched to control a circuit for performing the filtering process, the digital filter that is small in its circuit scale and low in its consumed electric power can be provided.

Further, in the digital filter according to the present invention, the second storing part further stores the output data of the multiplier, and outputs the output data of the multiplier as the first adding data in accordance with the state designated by the state control part.

According to this structure, for instance, when the coefficients of the digital filter have a symmetrization, the output data of the multiplier can be co-used as required, so that the circuit scale and the consumed electric power can be more suppressed.

Further, the digital filter according to the present invention further includes an order number setting part that sets the number of orders of the filter. The coefficient storing part includes a coefficient selecting part that selects the filter coefficients in accordance with the number of orders of the filter set by the order number setting part.

According to this structure, a calculation according to the number of orders of the filter can be carried out in an adaptable manner by a simple structure.

According to the present invention, a digital filter can be provided in which a circuit scale is small and a consumed electric power can be suppressed to a low level.

### BRIEF DESCRIPTION OF THE DRAWINGS

The above objects and advantages of the present invention will become more apparent by describing in detail preferred exemplary embodiments thereof with reference to the accompanying drawings, wherein:

FIG. 1 is a block diagram showing a schematic structure of a digital filter according to a first embodiment of the present invention;

FIG. 2 is a diagram showing one example of the structure of the digital filter;

FIG. 3 is a conceptual diagram showing one example of the calculation of the digital filter of the first embodiment of the present invention;

FIG. 4 is a conceptual diagram showing another example of the calculation of the digital filter of the first embodiment of the present invention;

FIG. 5 is a diagram showing a corresponding relation between a calculation state and the operation of the digital filter;

FIG. 6 is a block diagram showing the schematic structure of a digital filter according to a second embodiment of the present invention; and

FIG. 7 is a diagram showing a coefficient selecting table stored in a coefficient storing part in the second embodiment of the present invention.

### DETAILED DESCRIPTION OF THE PREFERRED EMBODIMENTS

A digital filter according to an embodiment of the present invention includes a multiplier, adders and storing parts for storing the outputs of these calculators. The digital filter sequentially switches a plurality of different calculation states to perform a calculation for one cycle and outputs the calculated result of the digital filter. Thus, the calculation of the filter can be carried out by the reduced number of the multiplier and the adders. Now, the embodiments of the present invention will be described by referring to the drawings.

### First Embodiment

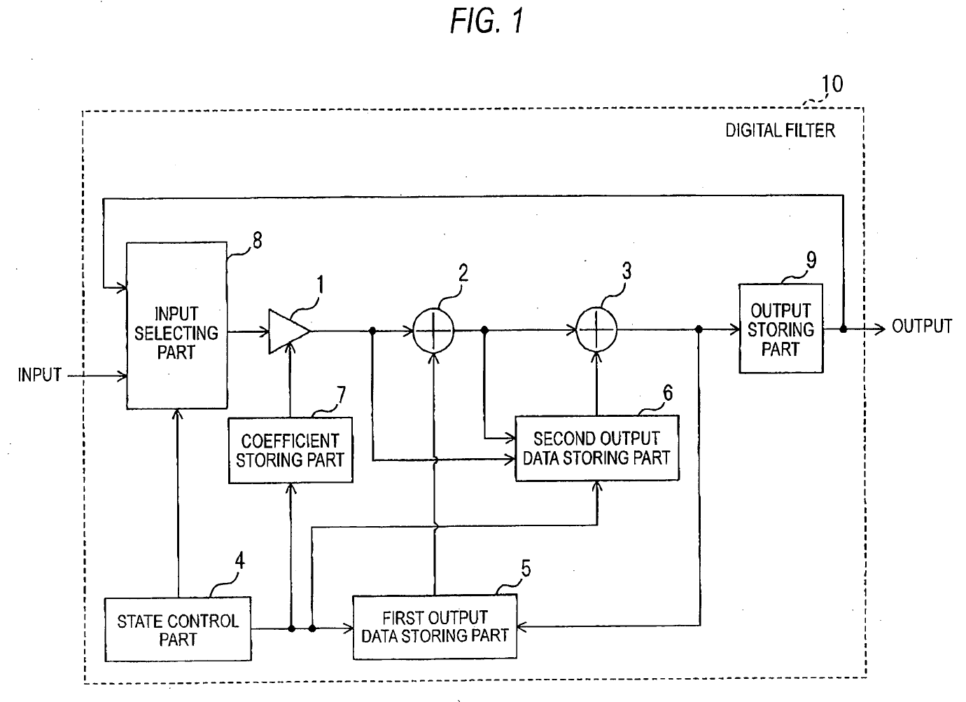

FIG. 1 is a block diagram showing the schematic structure of the digital filter according to the first embodiment of the present invention.

As shown in FIG. 1, a digital filter 10 of the first embodiment includes a multiplier 1, a first adder 2 connected to the output side of the multiplier 1 and a second adder 3 connected to the output side of the first adder 2.

Further, the digital filter 10 includes a state control part 4 for setting a plurality of different calculation states as one cycle and controlling the switching of the calculation states, a first output data storing part 5 for storing data outputted from the second adder 3, a second output data storing part 6 for storing data outputted from the multiplier 1 and the first adder 2, a coefficient storing part 7 for outputting coefficients to the multiplier 1, a selecting part 8 for selecting one of the input data or the output data of the digital filter 10 and outputting the data to the multiplier 1 and an output storing part 9 for storing the output data of the digital filter 10.

The multiplier 1 multiplies the data outputted from the input selecting part 8 by a multiplication coefficient outputted from the coefficient storing part 7. The data multiplied by the multiplier 1 is outputted to the first adder 2 and the second output data storing part 6.

The first adder 2 adds the data outputted from the multiplier 1 to first adding data outputted from the first output data storing part 5. The data added by the first adder 2 is outputted to the second adder 3 and the second output data storing part 6.

The second adder 3 adds the data outputted from the first adder 2 to second adding data outputted from the second output data storing part 6. The data added by the second adder 3 is outputted to the output storing part 9 and the first output data storing part 5.

The state control part 4 switches and controls the plurality of different calculation states of the digital filter 10. Every time the plurality of the calculation states are generally (one cycle) carried out, the output data of the digital filter 10 is obtained. Then, depending on the calculation state, a control signal is outputted to the first output data storing part 5, the second output data storing part 6, the coefficient storing part 7 and the input selecting part 8.

The first output data storing part 5 stores the data outputted from the second adder 3. Then, depending on the control signal outputted from the state control part 4, the stored data is outputted to the first adder 2 as the first adding data.

The second output data storing part 6 stores the output data of the multiplier 1 and the output data of the first adder 2. Then, depending on the control signal outputted from the state control part 4, the second output data storing part 6 outputs the stored data to the second adder 3 as the second adding data.

The coefficient storing part 7 stores a plurality of coefficients, selects a stored coefficient depending on the control signal outputted from the state control part 4 and outputs the coefficient to the multiplier 1 as the multiplication coefficient.

The input selecting part 8 selects one of the input data inputted to the digital filter 10 and the output data from the digital filter 10 outputted from the output storing part 9 and outputs the data to the multiplier 1.

The output storing part 9 stores the data obtained for each cycle including the plurality of different calculation states serving as at least the output of the digital filter 10. Then, the stored output data is outputted as the output data of the digital filter 10 and outputted to the input selecting part 8.

Now, an operation of the digital filter 10 of this embodiment will be described below.

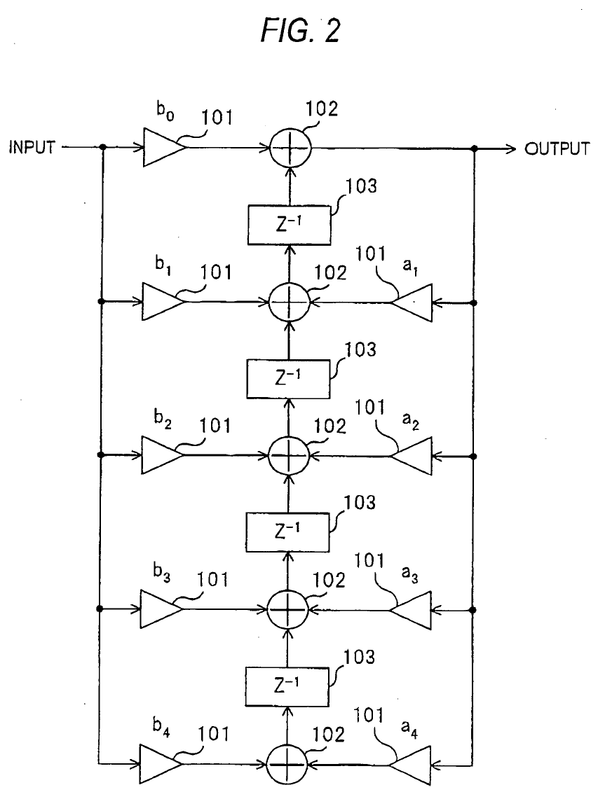

FIG. 2 is a diagram showing one example of a structure of a digital filter. As shown in FIG. 2, the digital filter 100 is formed as shown in a block diagram of FIG. 2 by using multipliers 101, adders 102 and delay devices 103.

In the block diagram of the digital filter shown in FIG. 2, the number of orders of the filter is set to four for convenience' sake. However, the number of orders is increased or decreased depending on the characteristics of the filter. In the following description, the number of orders of the filter is also set to four. However, the present invention is not limited to the four orders and any of orders may be employed.

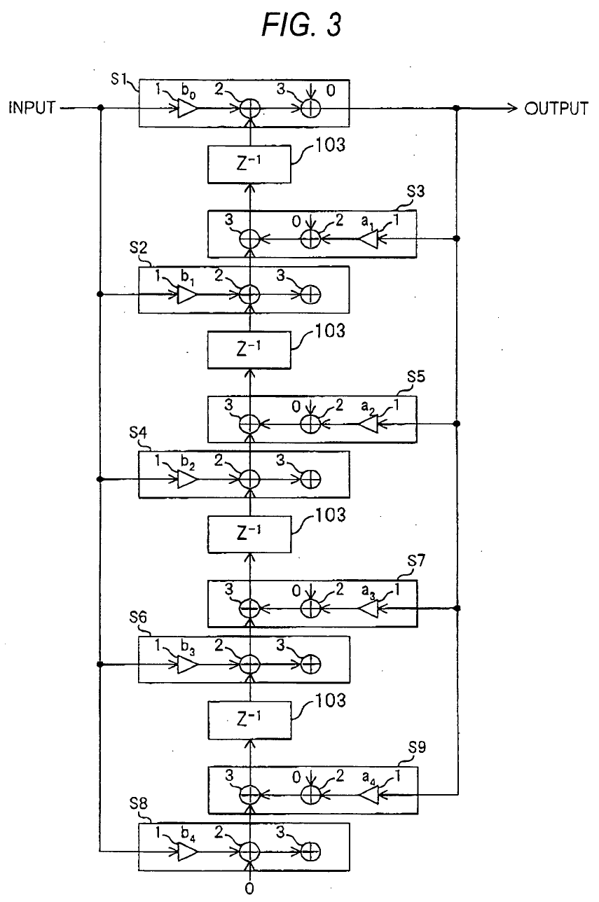

Further, a circuit shown in FIG. 2 may be modified as illustrated in a block diagram shown in FIG. 3. FIG. 3 is a conceptual view showing one example of the calculation of the digital filter of the first embodiment of the present invention. That is, the calculation is carried out depending on the plurality of calculation states (refer them to as states, hereinafter) by using the one multiplier 1 and the two adders 2 and 3 provided in the digital filter 10 shown in FIG. 1, and, the storing parts 5 and 6 serve as delay devices 103 shown in FIG. 3 that are used in the states respectively. Thus, the number of the multipliers or the adders can be suppressed and the calculation of the digital filter can be performed. In the case of the above-described calculation, the second output data storing part 6 may store only the output data of the first adder 2 and does not need to store the output data from the multiplier 1.

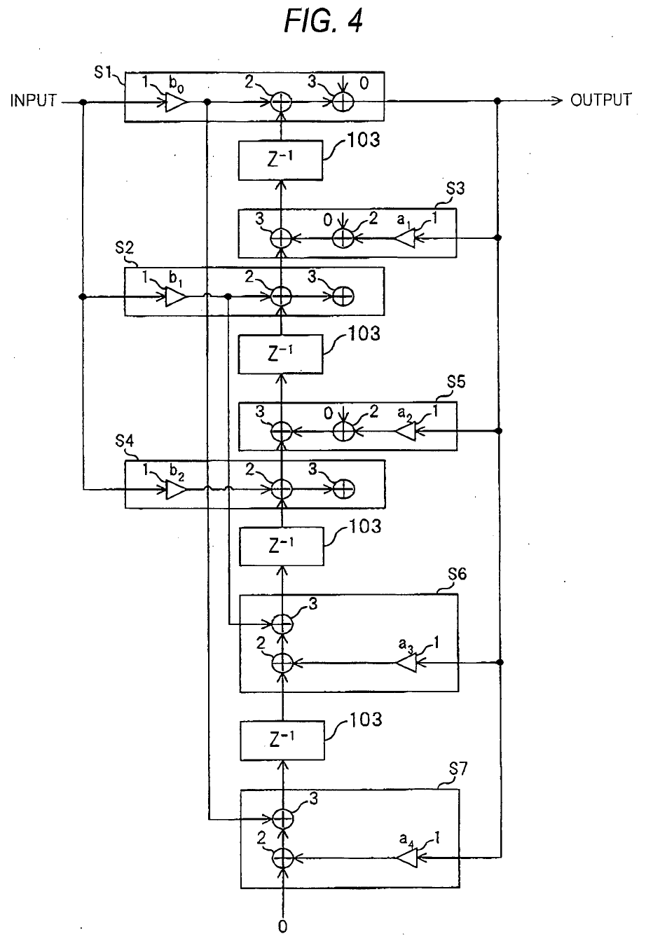

Further, the coefficients b0 to b4 of the digital filter ordinarily have a symmetrization. By taking the symmetrization into consideration, a structure shown in FIG. 3 can be modified to a structure as shown in FIG. 4. Accordingly, the circuit shown in FIG. 2 can be modified to the structure as shown in FIG. 4. FIG. 4 is a conceptual view showing another example of the calculation of the digital filter of the first embodiment of the present invention.

As described above, since the coefficient b0 is equal to b4 and b1 is equal to b3 owing to the symmetrization of the digital filter, the state control part 4 of the digital filter controls the state shown in FIG. 4 to sequentially shift states from a state 1 to a state 7.

The calculation using the multiplier 1 and the adders 2 and 3 is carried out for each state and the output data thereof is stored in the storing parts 5 and 6. Then, the switching timing of the state is controlled by the state control part 4 so that a function shown by delay elements 103 shown in FIG. 4 is realized.

The digital filter 10 repeats the calculation shown in FIG. 2 at intervals of prescribed time and the state control part 4 sets the state 1 to the state 7 shown in FIG. 4 as one cycle and repeatedly shifts the states of the one cycle.

The first output data storing part 5 and the second output data storing part 6 store the output data of the multiplier 1, the first adder 2 and the second adder 3 and output the data as the input data of the first adder 2 and the second adder 3 in accordance with the control signal outputted from the state control part 4.

The coefficient storing part 7 selects the coefficient depending on the state of the state control part 4 and outputs the coefficient to the multiplier 1. The output storing part 9 stores the output of the digital filter during one cycle in which the state control part makes a round of the states. The input selecting part 8 selects the input and the output of the digital filter 10 depending on the state of the state control part 4.

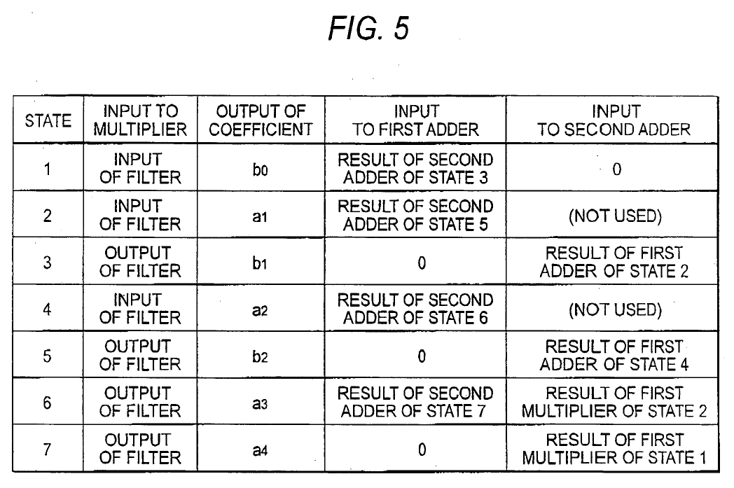

FIG. 5 is a diagram showing a corresponding relation between a calculation state and an operation of the digital filter. Examples of selecting input signals to the multiplier 1, the first adder 2 and the second adder 3 are shown for each state in the filter of four orders.

As shown in FIG. 5, every time the state is changed, the multiplier 1, the first adder 2 and the second adder 3 carry out the calculation of input data selected depending on the state of the state control part 4 so that the processes of the digital filter can be performed.

According to the above-described first embodiment of the present invention, the input data is selected and calculated to the multiplier 1, the first adder 2 and the second adder 3 in accordance with the plurality of the calculation states. Thus, the digital filter small in its scale and low in its consumed electric power can be provided.

Further, the state of the calculation is suppressed by considering the symmetrization of the filter coefficients, so that a quantity of calculation can be reduced.

### Second Embodiment

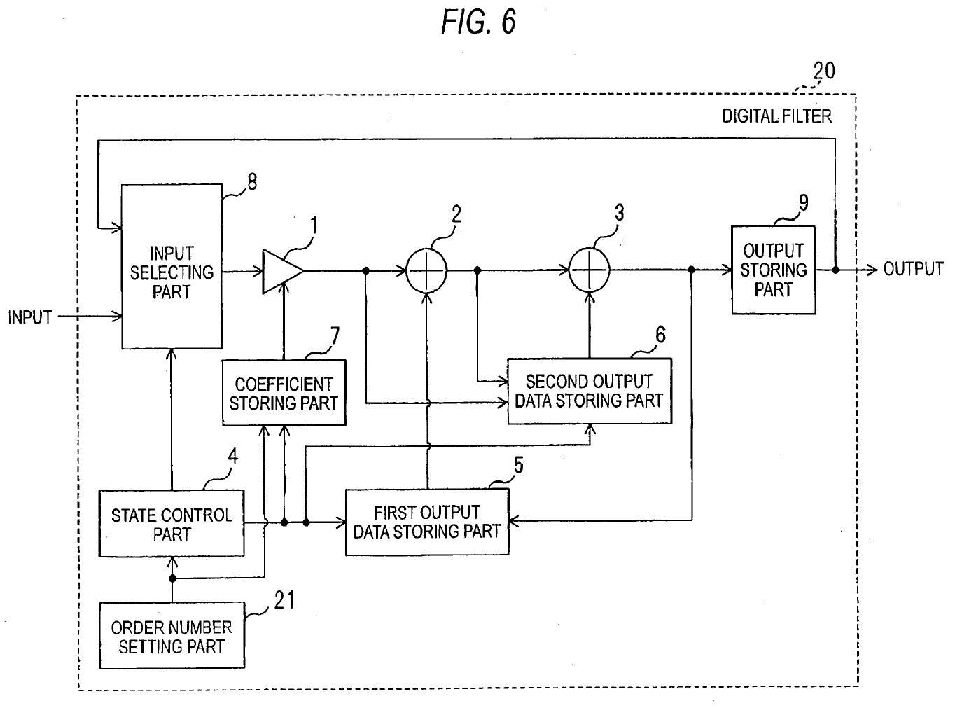

FIG. 6 is a block diagram showing a schematic structure of a digital filter according to a second embodiment of the present invention. Parts duplicated with those of the digital filter of the first embodiment shown in FIG. 1 are designated by the same reference numerals.

As compared with the digital filter 10 of the first embodiment, a digital filter 20 of this embodiment further includes an order number setting part 21. The order number setting part 21 sets the number of orders of the calculation of the filter in accordance with an input by a user or prescribed conditions and outputs a setting signal. The setting signal outputted from the order number setting part 21 is outputted to a state control part 4 and a coefficient storing part 7.

The state control part 4 controls a state in accordance with the set number of orders. The coefficient storing part 7 stores the number of orders of the calculation of the filter correspondingly to coefficients. Further, the coefficient storing part selects the stored coefficient on the basis of the set number of orders and a control signal from the state control part 4 and outputs the coefficient to a multiplier 1.

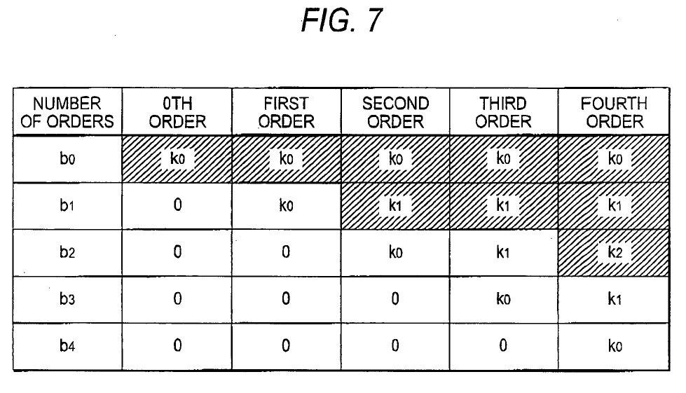

FIG. 7 is a diagram showing a coefficient selecting table stored in the coefficient storing part in the second embodiment of the present invention. As described in the first embodiment, since the coefficients b0 to bm of the digital filter of m orders ordinarily have a symmetrization, the coefficients are expressed by bi=bm−i. Here, i is an integer represented by 0≦i≦m.

Accordingly, as shown in FIG. 7, the coefficients need to be set are located in meshed parts in the table. Parts except them are selected depending on the number of orders of the filter. The coefficient of the filter is selected from k0 to k2 set as the coefficients of the filter is selected depending on the number of orders of the filter and outputted to the multiplier 1.

As described above, in the digital filter of the second embodiment of the present invention, an order number storing part and a coefficient selecting part are provided in the coefficient storing part in addition to the first embodiment, so that a digital filter smaller in its scale can be provided.

The digital filter of the present invention is advantageously applied to a digital filter that is small in its circuit scale, can effectively suppress a consumed electric power to a low level and is used for removing noise from an observed signal including the noise to take out a desired signal component.

Although the invention has been illustrated and described for the particular preferred embodiments, it is apparent to a person skilled in the art that various changes and modifications can be made on the basis of the teachings of the invention. It is apparent that such changes and modifications are within the spirit, scope, and intention of the invention as defined by the appended claims.

The present application is based on Japan Patent Application No. 2004-374225 filed on Dec. 24, 2004, the contents of which are incorporated herein for reference.
1 . . . multiplier
2 . . . first adder
3 . . . second adder
4 . . . state control part
5 . . . first output data storing part
6 . . . second output data storing part
7 . . . coefficient storing part
8 . . . input selecting part
9 . . . output storing part
10, 20 . . . digital filter
21 . . . order number setting part

What is claimed is:

1. A digital filter for performing a filtering process on inputted data to output the output data, the digital filter comprising:
a multiplier that multiplies the inputted data by a prescribed multiplication coefficient;
a first adder that adds the output data of the multiplier to first adding data;
a second adder that adds the output data of the first adder to second adding data;
a state control part that controls to switch of a plurality of different calculation states, the calculation states being set as one cycle;
a first storing part that stores the output data of the second adder, and outputs the output data of the second adder to the first adder as the first adding data in accordance with a state designated by the state control part;
a second storing part that stores the output data of the first adder, and outputs the output data of the first adder to the second adder as the second adding data in accordance with a state designated by the state control part;
a coefficient storing part that stores a plurality of filter coefficients and outputs the filter coefficient to the multiplier as the multiplication coefficient in accordance with the state designated by the state control part;
an output storing part that stores the output data of the second adder for each cycle; and
an input switching part that switches the data inputted to the multiplier to either the input data to the digital filter or the data stored in the output storing part in accordance with the state designated by the state control part.

2. The digital filter according to claim 1, wherein the second storing part further stores the output data of the multiplier, and outputs the output data of the multiplier as the first adding data in accordance with the state designated by the state control part.

3. The digital filter according to claim 1, further comprising:
an order number setting part that sets the number of orders of the filter,
wherein the coefficient storing part includes a coefficient selecting part that selects the filter coefficients in accordance with the number of orders of the filter set by the order number setting part.
